(19) United States
(12) Patent Application Publication
(10) Pub. No.: US 2026/0327487 A1
(43) Pub. Date: Oct. 22, 2026

(54) PEROVSKITE NANOCRYSTAL, METHOD FOR PREPARING THE SAME, PEROVSKITE NANOCRYSTAL THIN FILM COMPRISING THE SAME, AND OPTOELECTRONIC DEVICE

(71) Applicants: Foundation of Soongsil University-Industry Cooperation, Seoul (KR); IUCF-HYU (Industry-University Cooperation Foundation Hanyang University), Seoul (KR)

(72) Inventors: Min-Ho PARK, Seoul (KR); Tae-Hee HAN, Seoul (KR); Do-Young KIM, Seoul (KR); Gi-Jeong PARK, Seoul (KR)

(73) Assignee: IUCF-HYU(Industry-University Cooperation Foundation Hanyang University), Seoul (KR)

(21) Appl. No.: 19/563,443

(22) Filed: Mar. 11, 2026

(30) Foreign Application Priority Data
Mar. 12, 2025 (KR) 10-2025-0032328
Mar. 11, 2026 (KR) 10-2026-0043803

(51) Int. Cl. C09K 11/61; C01G 3/00; C09K 111/00; H10K 50/11

(52) U.S. Cl. CPC C09K 11/616; C01G 3/006; H10K 50/11; C01P 2002/34; C01P 2002/54; C01P 2004/03; C01P 2006/60; C09K 2111/00

(57) ABSTRACT

Disclosed are a perovskite nanocrystal, a method for preparing the same, a perovskite nanocrystal thin film including the same, and an optoelectronic device. The perovskite nanocrystal is a nickel (Ni)-doped copper (Cu)-based lead-free perovskite nanocrystal.

### CROSS-REFERENCE TO RELATED APPLICATION

This application claims priority to and the benefit of Korean Patent Application No. 10-2025-0032328 filed with the Korean Intellectual Property Office on Mar. 12, 2025, and Korean Patent Application No. 10-2026-0043803 filed with the Korean Intellectual Property Office on Mar. 11, 2026, the entire contents of which are incorporated herein by reference.

### BACKGROUND OF THE INVENTION

### (a) Field of the Invention

A perovskite nanocrystal, a method for preparing the same, a perovskite nanocrystal thin film comprising the same, and an optoelectronic device are disclosed.

### (b) Description of the Related Art

With the development of next-generation display and lighting technology, technical demands for high-performance optoelectronic devices are continuously increasing. Perovskite is attracting attention as a key material for such optoelectronic devices, and its potential is highly evaluated because it may be manufactured in the form of a thin film through a low-cost solution process. However, when forming a perovskite thin film by a solution process, defects in the material itself or non-uniformity of the thin film, which inevitably occur, have been pointed out as common problems that degrade the luminous efficiency and stability of the device.

Among these problems, as part of an effort to improve the intrinsic properties of the material, research on eco-friendly copper (Cu)-based lead-free perovskite that may solve the problem of the harmfulness of lead (Pb) is being actively conducted. To increase the stability of such copper-based perovskites, an approach of doping with heterogeneous metal ions has been widely attempted, but conventional technology has shown clear limitations.

For example, when a copper-based perovskite is doped with a metal such as manganese (Mn), the intrinsic energy band structure of the perovskite is deformed, resulting in a problem in that the intrinsic photoluminescence (PL) wavelength moves significantly in an undesired direction. This is a fatal disadvantage in the development of a light emitting device that must precisely realize a target color.

Therefore, there is a demand for the development of a new concept material and doping technology that may selectively improve only other physical properties, such as stability and thin film formation property, while maintaining the intrinsic emission color of nanocrystals, which are the constituent units of a thin film.

### SUMMARY OF THE INVENTION

An embodiment aims to provide a perovskite nanocrystal having simultaneously improved stability and thin film formation property while maintaining an intrinsic emission wavelength.

An embodiment provides a nickel (Ni)-doped copper (Cu)-based lead-free perovskite nanocrystal.

An embodiment may provide a perovskite nanocrystal having simultaneously improved stability and thin film formation property while maintaining an intrinsic emission wavelength.

### BRIEF DESCRIPTION OF THE DRAWINGS

FIG. 1 is a graph showing optical bandgap analysis results of undoped perovskite nanocrystals (Comparative Example 1) and nickel-doped perovskite nanocrystals (Examples 1 to 3) according to an embodiment.

FIG. 2 is a graph showing time-resolved photoluminescence (TRPL) life-span measurement results of undoped perovskite nanocrystals and nickel-doped perovskite nanocrystals according to an embodiment.

FIG. 3 is a graph showing photoluminescence (PL) spectrum analysis results of undoped perovskite nanocrystals and nickel-doped perovskite nanocrystals according to an embodiment.

FIG. 4 is a graph comparing photoluminescence intensity change (stability) over time for undoped perovskite nanocrystals and nickel-doped perovskite nanocrystals according to an embodiment.

FIG. 5 is an image observed by a scanning electron microscope (SEM) of the surface morphology according to the nickel doping concentration of a perovskite nanocrystal thin film according to an embodiment.

FIG. 6 is a view showing contact angle measurement results for distilled water (H₂O) and diiodomethane (CH₂I₂) according to whether nickel is doped or not in a perovskite nanocrystal thin film according to an embodiment.

### DETAILED DESCRIPTION OF THE EMBODIMENTS

Hereinafter, embodiments of the present invention will be described in detail. However, this is presented as an example, and the present invention is not limited thereby, and the present invention is only defined by the scope of the claims to be described later.

As used herein, when specific definition is not otherwise provided, it will be understood that when an element such as a layer, film, region, or substrate is referred to as being “on” another element, it can be directly on the other element or intervening elements may also be present.

As used herein, when specific definition is not otherwise provided, expressions in the singular may also include the plural. In addition, unless otherwise specified, “A or B” may mean “including A, including B, or including both A and B.”

As used herein, “a combination thereof” may mean a mixture of constituents, a laminate, a composite, a copolymer, an alloy, a blend, a reaction product, and the like.

### (Perovskite Nanocrystal)

An embodiment provides a nickel (Ni)-doped copper (Cu)-based lead-free perovskite nanocrystal.

By having the above configuration, an embodiment may provide a perovskite nanocrystal having simultaneously improved stability and thin film formation property while maintaining an intrinsic emission wavelength.

In this specification, ‘nanocrystal’ may refer to a particle in a 0 D (zero-dimensional) state. Herein, the 0 D state may be defined in one or more aspects.

For example, one aspect is based on physical properties and may refer to a state in which the size of the particle in all three-dimensional directions is smaller than the Exciton Bohr radius of a charge carrier, so that a quantum confinement effect appears clearly.

The other aspect is based on morphological characteristics and may refer to a state in which the particle does not extend in a specific direction like a nanowire (1 D) or a nanoplate (2 D), but has an equiaxed shape having similar dimensions in all directions.

Therefore, the ‘nanocrystal’ of an embodiment may be a term encompassing a quantum dot exhibiting a quantum confinement effect, or a nanoparticle that may be morphologically classified as 0 D even if its size slightly deviates from the quantum confinement effect region, and may have, for example, an average particle diameter of 2 to 30 nm.

Hereinafter, the perovskite nanocrystal of an embodiment will be described in detail.

### Host Material

The perovskite nanocrystal of an embodiment uses a copper (Cu)-based lead-free perovskite as a host material.

Despite the excellent performance of existing lead (Pb)-based perovskites, there is a major barrier to commercialization due to the problem of the harmfulness of lead to the human body and the environment. In contrast, the lead-free host material of an embodiment has the advantage of being eco-friendly as it is free from such harmfulness problems. In addition, among various lead-free compositions, copper (Cu)-based perovskite has the advantage of being a strong candidate material that may realize high luminous efficiency in the blue light region.

The host material of an embodiment may be represented by Chemical Formula 1.

A₃Cu₂-mNiₘX₅ [Chemical Formula 1]

In Chemical Formula 1, A is an alkali metal cation, X is a halogen anion, and m is a number representing the doping concentration and may be in a range of greater than 0 and 0.2 or less, and may mean, for example, the atomic content ratio of nickel (Ni) substituted for lattice sites of copper (Cu) in the host material.

For example, the A may be cesium (Cs⁺), and the X may be iodine (I⁻), in which case the host material is Cs₃Cu₂I₅.

### Dopant

In the perovskite nanocrystal of an embodiment, a part of the copper (Cu) cations of the host material is substituted (doped) with nickel (Ni) cations.

In the case of conventional manganese (Mn) doping, there was a problem in that the energy band structure of the perovskite was significantly changed due to the difference in ionic radius of the dopant, moving the intrinsic emission wavelength in an undesired direction. In contrast, an embodiment may solve this problem by using nickel (Ni) as a dopant.

The ionic radius (69 μm) of the nickel (Ni) cation is very similar to the ionic radius (74 μm) of the copper (Cu) cation of the host material, so that it may be stably substituted into the copper site without significantly distorting the crystal lattice structure of the host material.

### Characteristics of Perovskite Nanocrystal

The perovskite nanocrystal of an embodiment equipped with the above configuration may exhibit the following characteristics:
(1) Optical properties: The perovskite nanocrystal of an embodiment may exhibit excellent color purity while maintaining its intrinsic emission wavelength.

As described above, this results from the unique characteristic of nickel (Ni) doping that does not significantly distort the lattice structure of the host material, and may provide an advantage that precise control of emission color is possible.

For example, the perovskite nanocrystal of an embodiment may exhibit a photoluminescence (PL) peak wavelength in a range of 430 to 460 nm when measured with a photoluminescence spectrometer, and the full width at half maximum (FWHM) of the photoluminescence peak may be 90 nm or less.
(2) Stability: In the perovskite nanocrystal of an embodiment, long-term stability against the external environment may be dramatically improved through nickel doping.

This may be because nickel (Ni) ions are stably substituted into copper (Cu) sites, suppressing defects in nanocrystals and increasing resistance to chemical decomposition. Such an improvement in stability may directly determine the life-span of the device.

Such stability may be evaluated, for example, by tracking the change in photoluminescence intensity over time with a photoluminescence spectrometer while storing the nanocrystal dispersion solution under conditions of 25 °C and 50% relative humidity. As a result, the perovskite nanocrystal of an embodiment may maintain 80% or more of its initial photoluminescence intensity even after 28 days have elapsed at 25 °C and 50% relative humidity conditions.

### (Method for Preparing Perovskite Nanocrystal)

An embodiment provides a method for preparing a perovskite nanocrystal, the method including the steps of: preparing a first solution including an alkali metal precursor; preparing a second solution including a copper (Cu) precursor and a nickel (Ni) precursor; and mixing the first solution and the second solution at a high temperature to synthesize nickel-doped copper-based lead-free perovskite nanocrystals.

The perovskite nanocrystal of an embodiment is synthesized through a hot-injection method. Unlike a conventional method of forming a thin film by coating a precursor solution to a substrate and then heat-treating it, this has a differentiated advantage in that it is a method of directly synthesizing high-quality nanocrystals having a uniform composition and size starting from a solution state.

Accordingly, it is possible to provide an effective means for reproducibly synthesizing the perovskite nanocrystal of an embodiment described above.

Hereinafter, descriptions overlapping with those described above will be omitted, and the method for preparing a perovskite nanocrystal according to an embodiment will be described in detail.

### Preparation Step of Precursor Solution

First, a first solution including an alkali metal precursor may be prepared, and separately from this, a second solution including a copper (Cu) precursor and a nickel (Ni) precursor may be prepared.

Herein, pre-dissolving the nickel precursor, which is a dopant, together with the copper precursor of the host material in the second solution may be effective in realizing homogeneous doping by inducing the two ions to be uniformly and simultaneously (in-situ) introduced into the crystal lattice during subsequent nanocrystal growth.

The nickel precursor may be, for example, nickel iodide (NiI₂), nickel bromide (NiBr₂), nickel acetylacetonate (Ni(acac)₂), or the like.

In the above process, by adjusting the molar ratio (Ni/Cu) of the nickel (Ni) precursor to the copper (Cu) precursor included in the second solution within a range of 0.001 to 0.1, the nickel doping concentration (the ‘m’ value in Chemical Formula 1) of the finally synthesized perovskite nanocrystal may be precisely controlled.

### High-Temperature Synthesis Step

Thereafter, nanocrystals may be synthesized by mixing the first solution and the second solution at a high temperature.

Here, the high temperature may be, for example, in a range of 150 to 250 °C, and this may serve to provide activation energy required for nucleation and growth of nanocrystals. The mixing method may be performed by a hot-injection method in which another solution is rapidly injected into one solution maintained at a high temperature. This technique promotes uniform nucleation by inducing an instantaneous supersaturated state, and then high-quality nanocrystals with a very narrow size distribution (monodisperse) may be obtained through controlled growth.

### (Perovskite Nanocrystal Thin Film)

An embodiment provides a perovskite nanocrystal thin film including the perovskite nanocrystal according to an embodiment described above.

Such a thin film may be formed through a solution process of coating a nanocrystal dispersion solution onto a substrate and drying it, and may be used as a key component layer of a finally manufactured optoelectronic device.

In the perovskite nanocrystal of an embodiment, intrinsic surface characteristics may be changed through nickel doping, and this may act as a key advantage in a thin film formation process. Specifically, nickel-doped nanocrystals may exhibit an effect of lowering surface energy when forming a thin film. Low surface energy may suppress unnecessary aggregation between nanocrystals and improve dispersibility in a solvent, and may increase wettability with a substrate to allow the solution to spread more widely and uniformly.

As a result, the perovskite nanocrystal of an embodiment may form a high-quality thin film that has few defects such as pinholes, which were problems in conventional technology, and has a very uniform and dense surface morphology. Such a high-quality thin film may improve interfacial properties with upper and lower electrodes, and may reduce leakage current, serving as a basis for maximizing the performance and reliability of a finally manufactured optoelectronic device.

Hereinafter, descriptions overlapping with those described above will be omitted, and the perovskite nanocrystal thin film according to an embodiment will be described in detail.

### Surface Energy

The surface property of the thin film of an embodiment may be evaluated using a contact angle goniometer. For example, after dropping droplets of distilled water (H₂O) and diiodomethane (CH₂I₂) on the surface of the thin film to measure each contact angle, the surface energy may be calculated by substituting these into the Owens-Wendt model, which is a known model formula. At this time, the Owens-Wendt model is a method for calculating the surface energy of a thin film using surface tension components (dispersion component and polar component) of each liquid and the measured contact angles. As a result, the thin film of an embodiment may have a contact angle for distilled water (H₂O) in a range of 47 to 53°, and the calculated surface energy may be 52 mN/m or less.

### (Optoelectronic Device)

An embodiment provides an optoelectronic device including the perovskite nanocrystal thin film of an embodiment described above.

### Optoelectronic Device

The optoelectronic device may include, for example, various devices in which perovskite materials may be usefully used, such as a perovskite light emitting device, a solar cell, and a photodetector.

When the optoelectronic device is a light emitting device, it may include an anode, a cathode, and an emissive layer located between the anode and the cathode as a basic structure. In order to improve the efficiency and stability of the device, it may further include one or more functional layers interposed between the emissive layer and the electrodes.

Hereinafter, a case where the optoelectronic device is a perovskite light-emitting diode (PeLED) will be described in detail as an example.

In an embodiment, the perovskite nanocrystal thin film may be included as an emissive layer (EML) of a perovskite light emitting device. The emissive layer may be a key component of the device, where holes and electrons respectively injected from an anode and a cathode recombine to emit light.

The thin film according to an embodiment has a very uniform surface and few defects such as pinholes. Therefore, when used as an emissive layer, it may effectively form interfaces with a hole transport layer (HTL) and an electron transport layer (ETL) located above and below, and minimize non-radiative recombination loss due to interfacial defects. As a result, this may have the effect of increasing charge injection efficiency and suppressing leakage current, thereby significantly improving overall electrical stability and luminous efficiency (external quantum efficiency, EQE) of the device.

When individual nanocrystals constituting the emissive layer themselves have high photoluminescence quantum yield (PLQY), narrow full width at half maximum (FWHM), and excellent chemical stability, a final optoelectronic device including them may exhibit high color purity and long operating life-span.

Hereinafter, other configurations of the optoelectronic device will be described.

### Anode

The anode is an electrode for injecting holes and may be formed of a conductive material having a high work function. In the case of a bottom emission device that emits light from the substrate side, the anode may need to be transparent so that light may pass through. For example, the anode may be made of a transparent conductive oxide such as indium tin oxide (ITO), indium zinc oxide (IZO), or the like.

### Cathode

The cathode is an electrode for injecting electrons and may be formed of a conductive material having a low work function. For example, the cathode may include a metal such as aluminum (Al), magnesium (Mg), calcium (Ca), silver (Ag), or an alloy thereof.

### Hole Transport Layer (HTL)

The hole transport layer (HTL) is located between the anode and the emissive layer and may serve to help holes injected from the anode to smoothly move to the emissive layer. In an embodiment, the hole transport layer (HTL) may have a vertical composition gradient structure formed by self-assembly of a plurality of materials for improving device performance.

### Electron Transport Layer (ETL)

The electron transport layer (ETL) is located between the cathode and the emissive layer and may serve to efficiently transport electrons injected from the cathode to the emissive layer.

### Emissive Layer (EML)

The emissive layer may be a key component of the device, where holes and electrons respectively injected from an anode and a cathode recombine to emit light. In an embodiment, the emissive layer may be formed including perovskite nanocrystals.

### Solution Process

The thin film or functional layer according to an embodiment may be formed through a solution process. For the solution process, methods such as spin coating, doctor blading, inkjet printing, slot-die coating, screen printing, and roll-to-roll may be used. Such a solution process may be advantageous for manufacturing large-area devices at low cost without expensive vacuum deposition equipment.

Hereinafter, examples and comparative examples of the present invention are described. However, the following examples are only an embodiment of the present invention, and the present invention is not limited to the following examples.

### Comparative Example 1: Preparation of Undoped Cs₃Cu₂I₅ Nanocrystals

0.6 mmol of CuI was put into a flask together with 10 mL of 1-octadecene (ODE), 0.8 mL of oleylamine (OAm), and 0.8 mL of oleic acid (OA), and heated to 120-180 °C under a nitrogen (N₂) atmosphere to be completely dissolved. This solution was referred to as a first solution.

0.5 mL of a separately prepared 0.15 M Cs-oleate solution was rapidly injected into the first solution maintained at high temperature. After reacting for 10 seconds after injection, the reaction was immediately quenched by immersing in ice water.

The resulting nanocrystal solution was centrifuged to remove the supernatant, washed with ethyl acetate, and then redispersed in toluene to finally obtain an undoped Cs₃Cu₂I₅ nanocrystal dispersion solution.

### Examples 1 to 3: Preparation of Nickel (Ni)-Doped Cs₃Cu₂I₅ Nanocrystals

Performed in the same manner as Comparative Example 1, except that the doping concentration was varied by adjusting the input amount of the nickel precursor (NiI₂) relative to the copper precursor (CuI) when preparing the first solution.

Specifically, all conditions are the same as in Comparative Example 1, except that the amount of the nickel precursor was adjusted so that the molar ratio (Ni/Cu) of the nickel precursor (NiI₂) to the molar amount of the copper precursor (CuI) was 0.01, 0.03, and 0.05, respectively.
(1) Example 1: Ni/Cu molar ratio=0.01
(2) Example 2: Ni/Cu molar ratio=0.03
(3) Example 3: Ni/Cu molar ratio=0.05

### Evaluation Example 1: Structural Analysis and Optical Property Evaluation

Optical properties of each perovskite nanocrystal dispersion solution prepared in Comparative Example 1 and Examples 1 to 3 were evaluated as follows.

### (1) Structural Analysis

Structural characteristics of each perovskite nanocrystal prepared in Comparative Example 1 and Examples 1 to 3 were analyzed using an X-ray diffractometer (XRD) and a transmission electron microscope (TEM).

As a result, all Cs₃Cu₂I₅-based perovskite nanocrystals of Comparative Example 1 and Examples 1 to 3 exhibited the same XRD diffraction pattern matching the Cs₃Cu₂I₅ crystal structure of reference literature. This means that nickel doping did not change the intrinsic crystal structure of the host material.

In addition, as a result of TEM analysis, it was confirmed that uniform nanocrystals in a size range of 20 to 30 nm were formed in all samples.

Through this, it was proved that perovskite nanocrystals of the intended composition and morphology were successfully synthesized in all Comparative Examples and Examples.

### (2) Light Absorption and Optical Bandgap Analysis

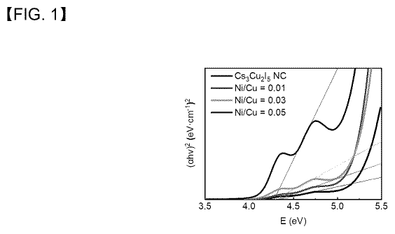

Ultraviolet-visible (UV-Vis) absorption spectra of each perovskite nanocrystal dispersion solution were measured using a UV-Vis spectrophotometer. An optical bandgap of each perovskite nanocrystal was calculated by plotting a Tauc plot ‘((αhv)₂ vs hv)’ from the measured absorption spectrum data, and the results are shown in Table 1 below and FIG. 1. Referring to FIG. 1, it can be seen that as the nickel doping concentration increases, the absorption edge moves slightly and the optical bandgap is systematically adjusted.

TABLE 1

| | | | Optical bandgap |
|---|---|---|---|
| | Host material | Dopant | (eV) |
| Comparative | Cs₃Cu₂I₅ | None | 4.35 |
| Example 1 | | | |
| Example 1 | Cs₃Cu₂I₅ | Ni | 4.33 |
| Example 2 | Cs₃Cu₂I₅ | Ni | 4.3 |
| Example 3 | Cs₃Cu₂I₅ | Ni | 4.28 |

As can be seen in Table 1 above, it was confirmed that for the perovskite nanocrystals of Examples 1 to 3, the optical bandgap systematically decreased as the nickel doping concentration increased.

### (3) Time-Resolved Photoluminescence (TRPL) Lifetime Analysis

Photoluminescence (PL) life-spans were measured for the perovskite nanocrystals of Comparative Example 1 and Examples 1 to 3 using time-resolved photoluminescence (TRPL) spectroscopy, and the results are shown in Table 2 below and FIG. 2. Through the TRPL decay curve in FIG. 2, it can be visually confirmed that upon nickel doping, nonradiative recombination is suppressed and the photoluminescence life-span is extended.

TABLE 2

| | | | PL life-span (τ, |
|---|---|---|---|
| | Host material | Dopant | μs) |
| Comparative | Cs₃Cu₂I₅ | None | 1.04 |
| Example 1 | | | |
| Example 1 | Cs₃Cu₂I₅ | Ni | 1.05 |
| Example 2 | Cs₃Cu₂I₅ | Ni | 1.06 |
| Example 3 | Cs₃Cu₂I₅ | Ni | 1.08 |

As a result of Table 2 above, in the case of the nickel-doped Examples, the PL life-span systematically increased slightly through doping. This means that the nonradiative recombination rate decreases by nickel doping, suggesting that this may contribute to more efficient light emission.

### Evaluation Example 2: Photoluminescence Property and Stability Evaluation

### (1) Photoluminescence (PL) Spectrum Analysis

Photoluminescence (PL) spectra of each perovskite nanocrystal dispersion solution prepared in Comparative Example 1 and Examples 1 to 3 were measured using a photoluminescence spectrometer.

As a result, all Cs₃Cu₂I₅-based perovskite nanocrystals of Comparative Example 1 (undoped) and Examples 1 to 3 (nickel-doped) exhibited a maximum peak wavelength at about 445 nm, and the full width at half maximum (FWHM) measured at this time was 90 nm or less, showing very excellent color purity. In this regard, FIG. 3 compares the PL spectra of Comparative Example 1 and Examples 1 to 3, and shows that the intrinsic emission color is maintained without shifting the peak wavelength even after nickel doping.

These results clearly show that the combination of doping ‘nickel’ into the ‘Cs₃Cu₂I₅ host material’, which is a key component of an embodiment, maintains the intrinsic emission wavelength constant without almost changing it. This is an unpredictable and significant effect completely distinguishable from other conventional metal doping technologies in which the emission wavelength changes significantly.

### (2) Stability Evaluation

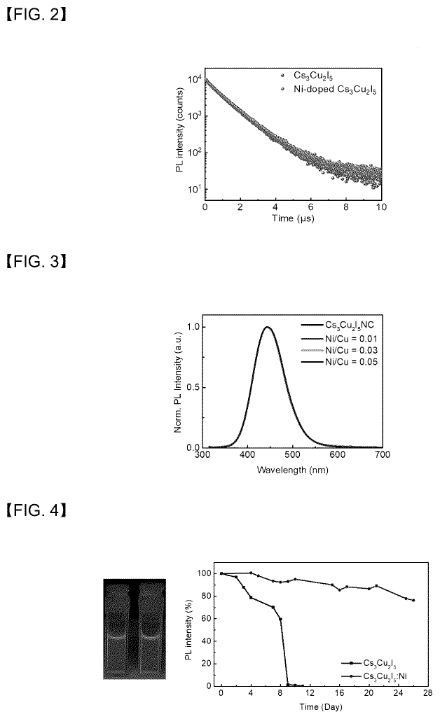

While storing the perovskite nanocrystal dispersion solutions of Comparative Example 1 and Example 3 under conditions of 25 °C and 50% relative humidity (RH), stability was evaluated by tracking the residual intensity (%) compared to the initial photoluminescence intensity after 28 days with a photoluminescence spectrometer. The results are shown in Table 3 and FIG. 4. Referring to FIG. 4, it can be seen that while the photoluminescence intensity of undoped nanocrystals rapidly decreases within a few days, the nickel-doped Example exhibits a remarkable stability improvement effect of maintaining high luminescence activity even after long-term storage of 28 days or more.

TABLE 3

| | | | Residual PL intensity after |
|---|---|---|---|
| | Host material | Dopant | 28 days (%) |
| Comparative | Cs₃Cu₂I₅ | None | <10% |
| Example 1 | | | |
| Example 3 | Cs₃Cu₂I₅ | Ni | >80% |

As a result of Table 3 above, only the perovskite nanocrystals of Example 3 doped with nickel stably maintained 80% or more of the initial intensity even after 28 days. This stability improvement effect is expected to be far superior to the case of non-doping (Comparative Example 1) or other metal doping. Through this, it was proved that the nickel doping according to an embodiment has an unpredictable effect of dramatically improving the stability of perovskite nanocrystals against the external environment.

### Evaluation Example 3: Thin Film Property Evaluation

Thin films were formed on substrates using each nanocrystal dispersion solution prepared in Comparative Example 1 and Example 3, and their properties were evaluated as follows.

### (1) Thin Film Surface Morphology Analysis

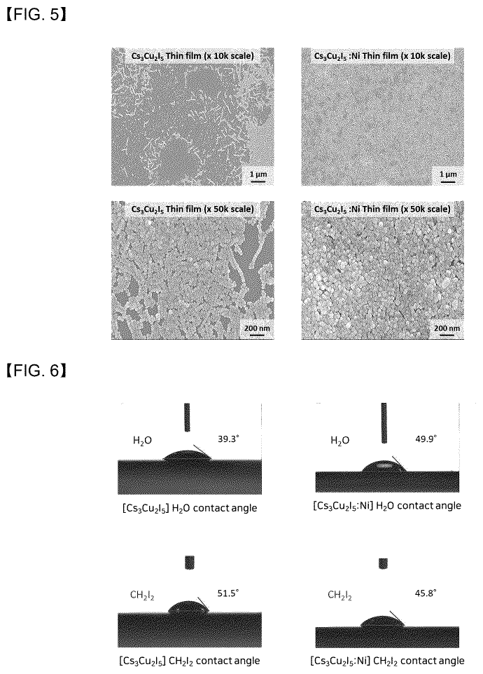

After spin-coating each nanocrystal dispersion solution on a substrate, thin films were produced by heat treatment. Thereafter, the surface morphology of each thin film was observed using a Scanning Electron Microscope (SEM). The uniformity and surface coverage degree of the thin film were evaluated by quantifying them on a numerical scale from 0 (very inferior) to 5 (very excellent), and the observation results are shown in Table 4 below and FIG. 5. Through the SEM image in FIG. 5, it can be seen that upon nickel doping, pinholes were suppressed and a high-quality thin film in which particles were densely arranged was formed.

TABLE 4

| | | | Thin film qualty |
|---|---|---|---|
| | Host material | Dopant | (0~5) |
| Comparative | Cs₃Cu₂I₅ | None | 2 |
| Example 1 | | | |
| Example 3 | Cs₃Cu₂I₅ | Ni | 5 |

As can be seen in Table 4 above, it was confirmed that for the perovskite nanocrystals of the Example, the quality score of the thin film significantly improved as the nickel doping concentration increased. This means that nickel doping plays a specifically excellent role in improving the surface coverage of the thin film.

### (2) Thin Film Surface Energy Analysis

Surface energy was analyzed for the thin films of Comparative Example 1 and Examples 1 to 3. This was evaluated using a contact angle goniometer. Specifically, after dropping droplets of distilled water (H₂O) and diiodomethane (CH₂I₂) on the surface of the thin film to measure contact angles, surface energy was calculated by substituting the measured values into a known model formula (e.g., Owens-Wendt model). The results are shown in Table 5 and FIG. 6. From the contact angle measurement results in FIG. 6, it was proved that nickel doping is a direct cause of changing the surface properties of the thin film to improve wettability and coating property with the substrate.

TABLE 5

| | | | Surface energy |
|---|---|---|---|
| | Host material | Dopant | (mN/m) |
| Comparative | Cs₃Cu₂I₅ | None | 56.05 |
| Example 1 | | | |
| Example 3 | Cs₃Cu₂I₅ | Ni | 50.18 |

As a result of Table 5 above, Example 3 shows that the surface energy of the thin film decreases according to nickel doping. Such a surface energy reduction effect is specific to nickel doping and is expected not to be observed in other conventional metal doping technologies. Since low surface energy improves the dispersibility of nanocrystals during a solution process and promotes uniform coating on a substrate, it becomes direct evidence supporting the thin film quality improvement results of (1) above.

### CONCLUSION

Synthesizing the results of Evaluation Examples 1 to 3, the specific combination of ‘Cs₃Cu₂I₅ host material’ and ‘nickel (Ni) dopant’ according to an embodiment exhibits combined effects of (1) maintaining an intrinsic blue emission wavelength, (2) dramatically improving stability against the external environment, and (3) maximizing thin film quality by effectively lowering the surface energy of the thin film. Such a synergistic effect is an unpredictable result not observed at all in the case where doping is simply not performed (Comparative Example 1). Therefore, the Evaluation Examples clearly demonstrate the remarkable technical superiority and progressiveness of an embodiment overcoming the limitations of conventional technology.

While preferred embodiments of the present invention have been described above, the present invention is not limited thereto, and various modifications may be made within the scope of the claims, the detailed description of the invention, and the accompanying drawings, which also naturally fall within the scope of the present invention.

1. A nickel (Ni)-doped copper (Cu)-based lead-free perovskite nanocrystal.

2. The perovskite nanocrystal of claim 1, wherein
the nanocrystal is a perovskite nanocrystal represented by Chemical Formula 1:
A₃Cu₂-mNiₘX₅ [Chemical Formula 1]
wherein, A is an alkali metal cation, X is a halogen anion, and m is greater than 0 and 0.2 or less.

3. The perovskite nanocrystal of claim 2, wherein
the A is cesium (Cs⁺), and the X is iodine (I).

4. The perovskite nanocrystal of claim 1, wherein
the nanocrystal is a perovskite nanocrystal exhibiting a photoluminescence (PL) peak wavelength in a range of 430 to 460 nm.

5. The perovskite nanocrystal of claim 4, wherein
a full width at half maximum (FWHM) of the photoluminescence peak is 90 nm or less.

6. The perovskite nanocrystal of claim 1, wherein
the nanocrystal maintains 80% or more of its initial photoluminescence intensity after 28 days have elapsed at 25 °C and 50% relative humidity conditions.

7. A method for preparing a perovskite nanocrystal, comprising
preparing a first solution comprising an alkali metal precursor;
preparing a second solution comprising a copper (Cu) precursor and a nickel (Ni) precursor; and
mixing the first solution and the second solution at a high temperature to synthesize nickel-doped copper-based lead-free perovskite nanocrystals.

8. The method for preparing the perovskite nanocrystal of claim 7, wherein
the mixing of the first solution and the second solution is performed by a hot-injection method in which the second solution is injected into the first solution, or the first solution is injected into the second solution.

9. The method for preparing the perovskite nanocrystal of claim 7, wherein
a molar ratio (Ni/Cu) of the nickel (Ni) precursor to the copper (Cu) precursor included in the second solution is in a range of 0.001 to 0.1.

10. The method for preparing the perovskite nanocrystal of claim 7, wherein
the high temperature is in a range of 150 to 250 °C.

11. A perovskite nanocrystal thin film comprising the perovskite nanocrystal according to claim 1.

12. The perovskite nanocrystal thin film of claim 11, wherein
the thin film has a contact angle for distilled water (H₂O) in a range of 47 to 53°.

13. The perovskite nanocrystal thin film of claim 11, wherein
a surface energy of the thin film is 52 mN/m or less.

14. An optoelectronic device comprising the thin film according to claim 11.

15. The optoelectronic device of claim 14, wherein
the optoelectronic device is a perovskite light emitting device, and
the thin film is included as an emissive layer.
